(19) United States
(12) Patent Application Publication
(10) Pub. No.: US 2015/0216082 A1
(43) Pub. Date: Jul. 30, 2015

(54) HEAT DISSIPATION MECHANISM FOR HANDHELD ELECTRONIC APPARATUS

(71) Applicant: Tsung-Hsien Huang, I-Lan Hsien (TW)

(72) Inventor: Tsung-Hsien Huang, I-Lan Hsien (TW)

(21) Appl. No.: 14/252,561

(22) Filed: Apr. 14, 2014

(30) Foreign Application Priority Data
Jan. 24, 2014 (CN) 201410034217.4

(51) Int. Cl. H05K 7/20

(52) U.S. Cl. CPC H05K 7/20336; H05K 7/2039

(57) ABSTRACT

A heat dissipation mechanism for handheld electronic apparatus includes a thin metal sheet having spaced integral clamping plates, and one or multiple heat pipes attached to the clamping plates and secured thereto. After insertion of each heat pipe into the clamping plates, the clamping plates are deformed to wrap about the loaded heat pipe(s).

### BACKGROUND OF THE INVENTION

(a) Field of the Invention

The present invention relates to heat dissipation technology, and more particularly to a heat dissipation mechanism for handhold electronic apparatus, which comprises a thin metal sheet and at least one heat pipe joined to the thin metal sheet.

(b) Description of the Prior Art

With rapid progress of technology, many different handheld electronic apparatuses, such as cell phone, notebook computer, tablet computer, iPad, PDA, GPS etc., have been continuously created. These advanced handheld electronic apparatuses have the characteristics of low profile, light weight and compact size. Further, due to high operating speed, the internal CPU and other IC components of these advanced handheld electronic apparatuses generate a large amount of waste heat during operation. Such waste heat must be quickly dissipated to ensure normal functioning of the heat emitting component and to sustain its lifespan.

In order to fit the low-profile characteristic of a handheld electronic apparatus, conventional heat dissipation mechanisms commonly comprise a thin metal sheet for directly bonding to a CPU or heat-emitting component of a handheld electronic apparatus for heat dissipation. This technique has low heat dissipation performance and cannot dissipate heat rapidly. Waste heat can easily be accumulated in the handheld electronic apparatus, causing system halt or component damage.

### SUMMARY OF THE INVENTION

The present invention has been accomplished under the circumstances in view. It is therefore the main object of the present invention to provide a heat dissipation mechanism for handheld electronic apparatus. The heat dissipation mechanism comprises a thin metal sheet and at least one heat pipe mounted at the thin metal sheet. The thin metal sheet comprises a plurality of integral clamping plates adapted for receiving the at least one heat pipe. Each clamping plate has at least one of two opposite lateral sides thereof deformable to wrap about one heat pipe. After installation of the heat dissipation mechanism in a handheld electronic apparatus, the heat absorbing end of each heat pipe is kept in contact with a heat-emitting component of the handheld electronic apparatus, enabling heat to be rapidly carried away from the heat-emitting component. Thus, the heat dissipation mechanism enhances the heat dissipation performance of the handheld electronic apparatus, avoiding damage to the handheld electronic apparatus or its components.

Further, after insertion of each heat pipe in the clamping plates, a stamping technique is employed to deform one or two opposite sides of each of all the clamping plates, causing the clamping plates to wrap about the loaded heat pipe(s). Thus, the heat dissipation mechanism is easy to fabricate, and its cost is low. Further, the heat pipe(s) can be tightly secured to the thin metal sheet by the clamping plates without welding.

Further, the clamping plates can be made to have a U-shaped cross section. Thus, each clamping plate defines therein an accommodation space for accommodating one heat pipe. After loading of the heat pipe(s) in the clamping plates, the clamping plates are deformed to wrap about the heat pipe(s), securing the heat pipe(s) firmly to the thin metal sheet.

Further, the heat pipe can be a straight heat pipe, an angled heat pipe, a U-shaped heat pipe, or a flat heat pipe.

### BRIEF DESCRIPTION OF THE DRAWINGS

FIG. 1 is an exploded view of a heat dissipation mechanism for handheld electronic apparatus in accordance with a first embodiment of the present invention.

FIG. 2 is a perspective view of the first embodiment of the present invention, illustrating the heat pipe loaded prior to deformation of the clamping plates.

FIG. 3 is a schematic sectional view in an enlarged scale of a part of FIG. 2, illustrating the heat pipe set in the clamping plates.

FIG. 4 corresponds to FIG. 2, illustrating the clamping plates after they are deformed.

FIG. 5 corresponds to FIG. 3, illustrating the clamping plates after they are deformed.

FIG. 6 is an exploded view illustrating the use of the heat dissipation mechanism for handheld electronic apparatus in a cell phone in accordance with the first embodiment of the present invention

FIG. 7 is a top view of a heat dissipation mechanism for handheld electronic apparatus in accordance with a second embodiment of the present invention.

FIG. 8 is a top view of a heat dissipation mechanism for handheld electronic apparatus in accordance with a third embodiment of the present invention.

FIG. 9 is a top view of a heat dissipation mechanism for handheld electronic apparatus in accordance with a fourth embodiment of the present invention.

FIG. 10 is a top view of a heat dissipation mechanism for handheld electronic apparatus in accordance with a fifth embodiment of the present invention.

### DETAILED DESCRIPTION OF THE PREFERRED EMBODIMENTS

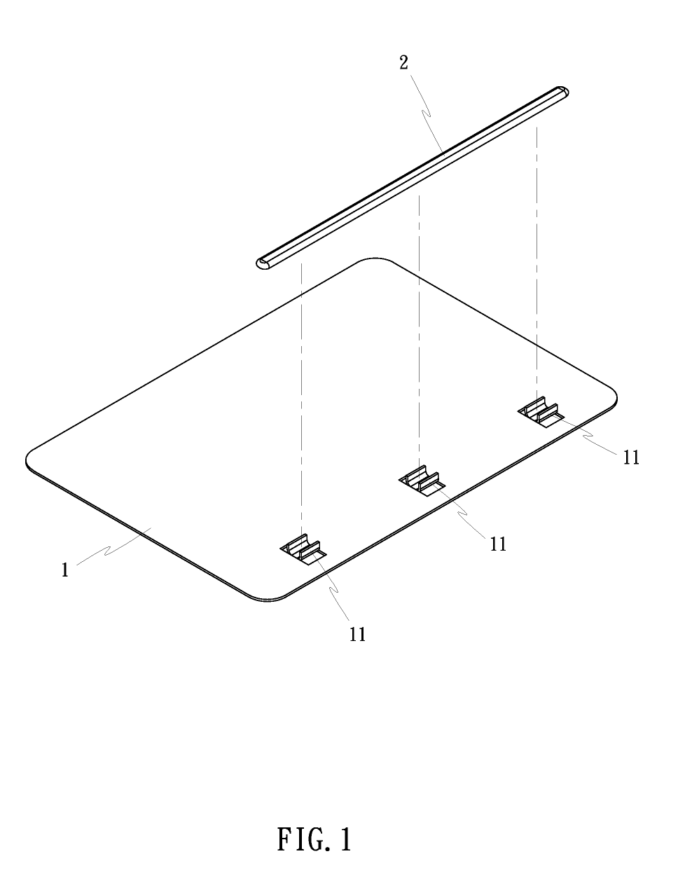

Referring to FIGS. 1-5, a heat dissipation mechanism for handhold electronic apparatus in accordance with a first embodiment of the present invention is shown. As illustrated, the heat dissipation mechanism comprises a thin metal sheet 1 and a heat pipe 2.

The thin metal sheet 1, as illustrated in FIG. 1, is a metal sheet having high heat transfer capability. The thin metal sheet 1 is stamped or machined to provide a set of clamping plates 11 arranged in a line for securing the heat pipe 2.

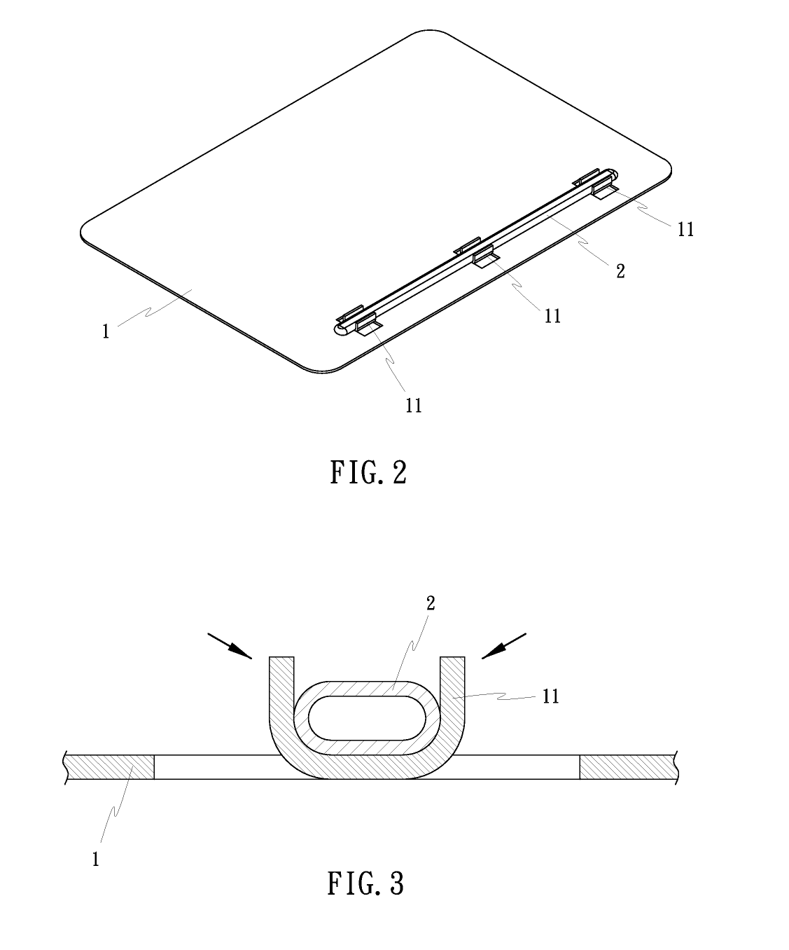

The heat pipe 2 is a flat pipe insertable into the clamping plates 11 (see FIG. 2).

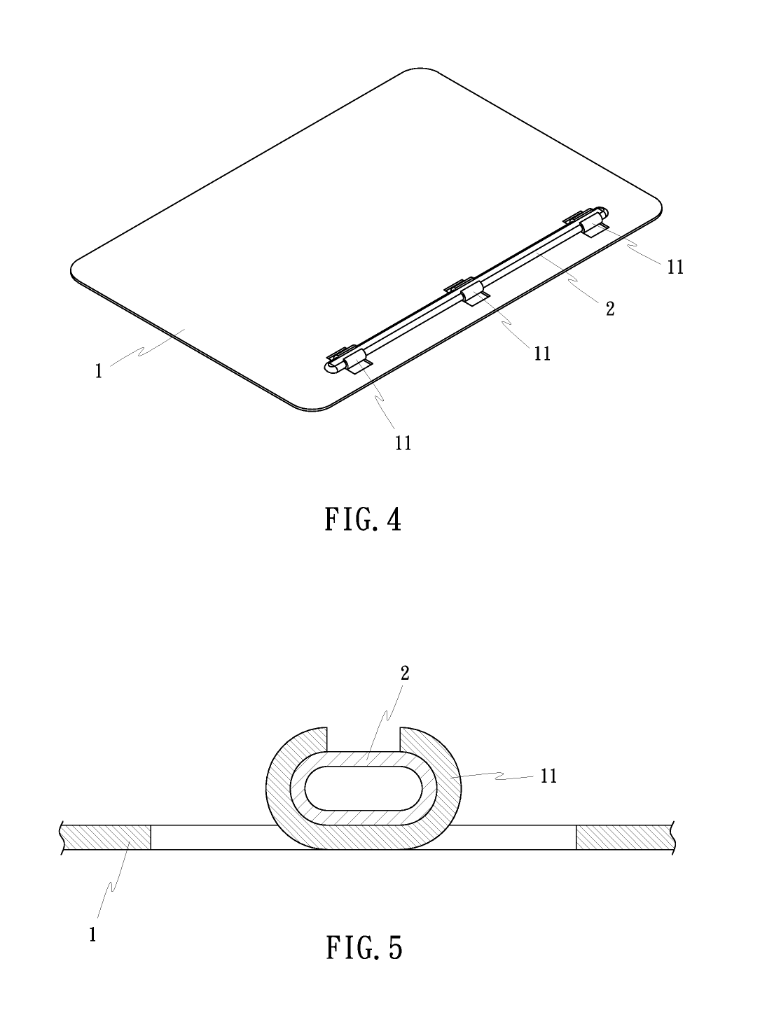

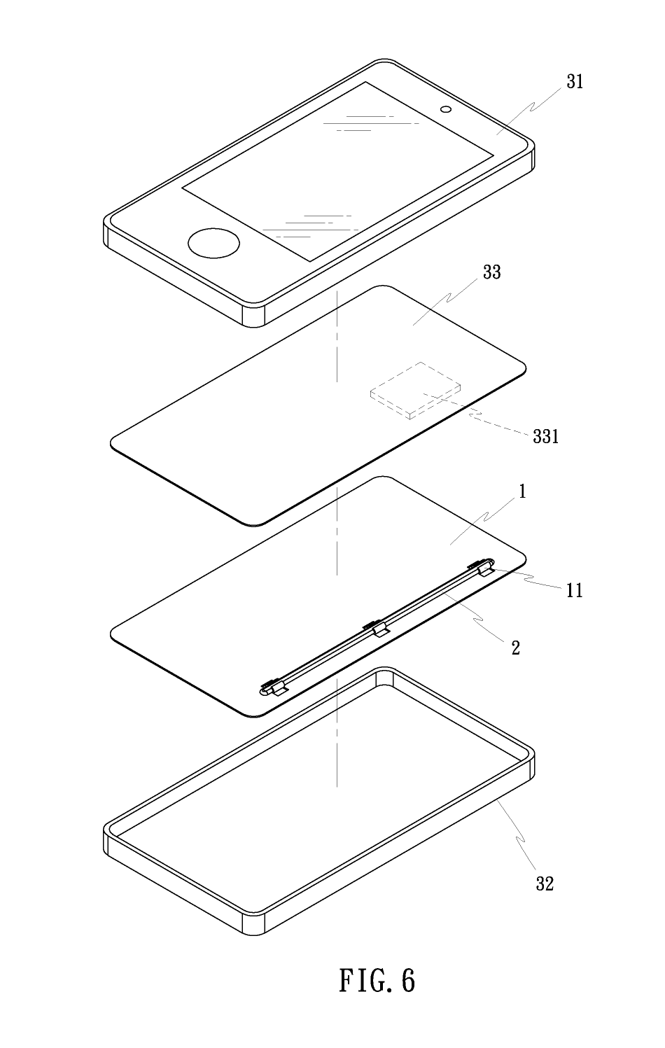

After insertion of the heat pipe 2 into the clamping plates 11, one side or two opposite sides of each clamping plate 11 are deformed (in the direction shown in FIG. 3) and wrapped about the heat pipe 2 (see FIG. 4 and FIG. 5).

Referring to FIG. 6, in one application example of the present invention, the heat dissipation mechanism is used in a cell phone. As illustrated, the cell phone comprises a top cover 31, a bottom cover 32, a circuit board 33 set in between the top cover 31 and the bottom cover 32 and carrying a heat-emitting component 331 (for example, CPU). The heat dissipation mechanism is set between the circuit board 33 and the bottom cover 32 to keep the heat absorbing end of the heat pipe 2 in direct contact with the heat-emitting component 331. Thus, the heat pipe 2 can absorb heat from the heat-emitting component 331 and transfer absorbed heat to the thin metal sheet 1 for quick dissipation, preventing accumulation of waste heat in the cell phone. Thus, the use of the heat dissipation mechanism enhances the heat dissipation performance of the cell phone, avoiding damage to the cell phone or its components.

Further, the clamping plates 11 of the thin metal sheet 1 have a substantially U-shaped cross section, defining therein an accommodation space for accommodating the heat pipe 2. After loading of the heat pipe 2 in the clamping plates 11, the clamping plates 11 are deformed to wrap about the heat pipe 2, securing the heat pipe 2 firmly to the thin metal sheet 1.

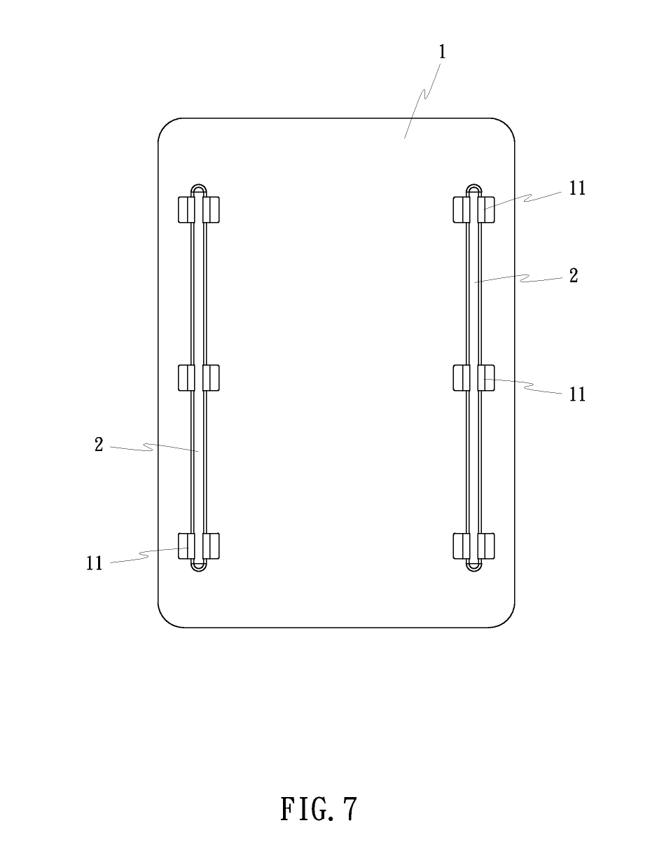

FIG. 7 illustrates a heat dissipation mechanism for handhold electronic apparatus in accordance with a second embodiment of the present invention. This second embodiment is substantially similar to the aforesaid first embodiment with the exception that two heat pipes 2 are respectively mounted in two sets of clamping plates 11 near two opposite lateral sides of the thin metal sheet 1.

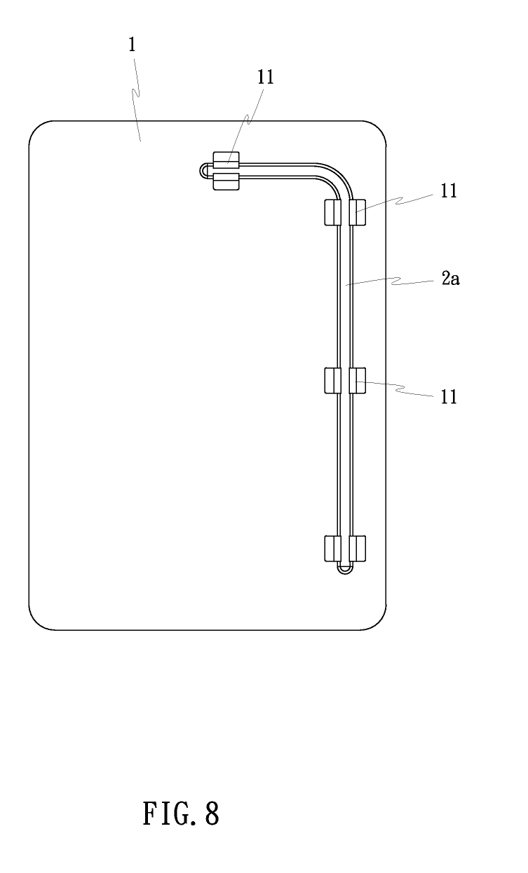

FIG. 8 illustrates a heat dissipation mechanism for handhold electronic apparatus in accordance with a third embodiment of the present invention. This third embodiment is substantially similar to the aforesaid first embodiment with the exception that the heat pipe 2a is an angled pipe secured to the thin metal sheet 1 by the clamping plates 11.

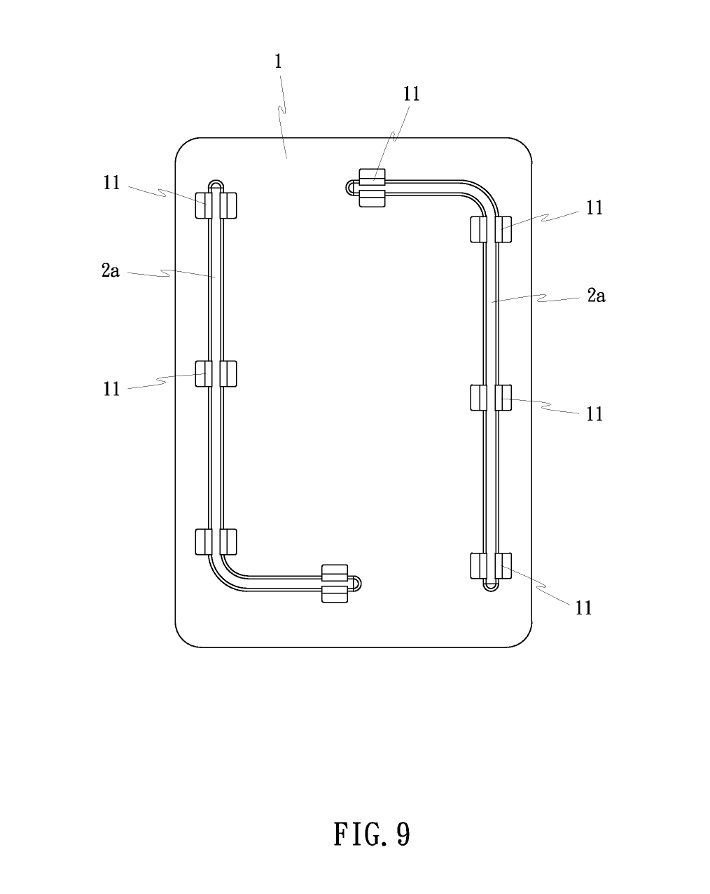

FIG. 9 illustrates a heat dissipation mechanism for handhold electronic apparatus in accordance with a fourth embodiment of the present invention. This fourth embodiment is substantially similar to the aforesaid third embodiment with the exception that two angled heat pipes 2 are respectively mounted in two sets of clamping plates 11 in two diagonal corners of the thin metal sheet 1.

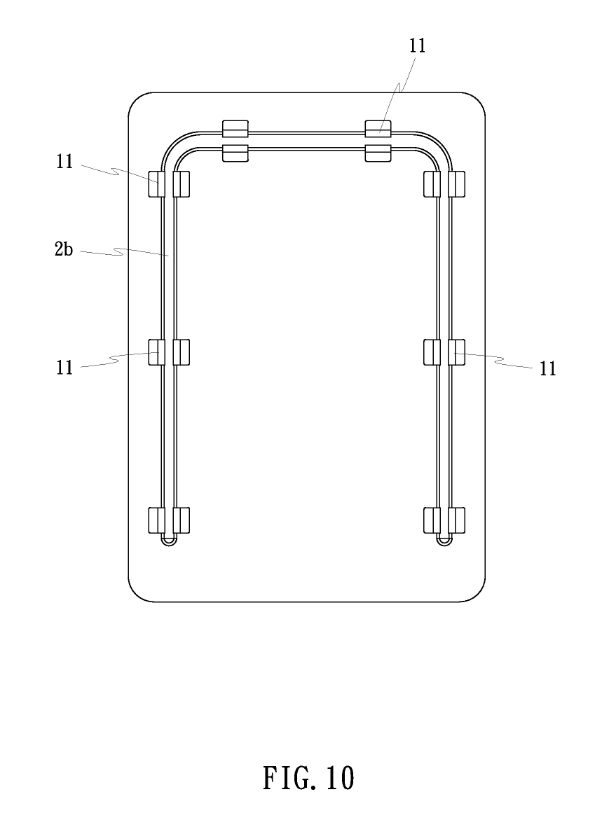

FIG. 10 illustrates a heat dissipation mechanism for handhold electronic apparatus in accordance with a fifth embodiment of the present invention. This fifth embodiment is substantially similar to the aforesaid first embodiment with the exception that the heat pipe 2b is a substantially U-shaped pipe mounted in the clamping plates 11 and extending along three adjacent sides of the thin metal sheet 1.

Further, the shape, size and distribution of the clamping plates 11 of the thin metal sheet 1 can be changed to fit different designs of heat pipes 2, 2a, 2b.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A heat dissipation mechanism for a handheld electronic apparatus, comprising a thin metal sheet and at least one heat pipe mounted at said thin metal sheet, wherein:
said thin metal sheet comprises a plurality of integral clamping plates adapted for receiving said at least one heat pipe, each said clamping plate having at least one of two opposite lateral sides thereof deformed to wrap about one said heat pipe.

2. The heat dissipation mechanism as claimed in claim 1, wherein each said heat pipe has a heat absorbing end thereof for making direct contact with a heat-emitting component of said handheld electronic apparatus.

3. The heat dissipation mechanism as claimed in claim 1, wherein said clamping plates each have a U-shaped cross section.

4. The heat dissipation mechanism as claimed in claim 1, wherein each said heat pipe is a straight heat pipe.

5. The heat dissipation mechanism as claimed in claim 1, wherein each said heat pipe is an angled heat pipe.

6. The heat dissipation mechanism as claimed in claim 1, wherein each said heat pipe is a U-shaped heat pipe.

7. The heat dissipation mechanism as claimed in claim 1, wherein each said heat pipe is a flat heat pipe.
